(19) United States
(12) Patent Application Publication
(10) Pub. No.: US 2024/0363692 A1
(43) Pub. Date: Oct. 31, 2024

(54) SILICON CARBIDE SEMICONDUCTOR DEVICE

(71) Applicant: FUJI ELECTRIC CO., LTD., Kawasaki-shi, Kanagawa (JP)

(72) Inventors: Takeshi TAWARA, Tsukuba-city (JP); Shinsuke HARADA, Tsukuba-city (JP)

(73) Assignee: FUJI ELECTRIC CO., LTD., Kawasaki-shi, Kanagawa (JP)

(21) Appl. No.: 18/626,631

(22) Filed: Apr. 4, 2024

(30) Foreign Application Priority Data
Apr. 26, 2023 (JP) 2023-072786

(51) Int. Cl. H01L 29/16; H01L 29/167; H01L 29/78; H01L 29/872

(52) U.S. Cl. CPC H01L 29/1608; H01L 29/167; H01L 29/7806; H01L 29/7832; H01L 29/872

(57) ABSTRACT

A semiconductor device, including: first to fourth semiconductor regions, the fourth semiconductor region containing a first-conductivity-type impurity having a higher concentration than the first semiconductor region; first and second trenches; a gate electrode provided in the first trench; a Schottky electrode formed at an inner wall of the second trench, and in contact with the fourth semiconductor region; and a first electrode embedded in the second trench and in contact with the Schottky electrode. The fourth semiconductor region includes: an SBD portion formed at a sidewall of the second trench and in contact with the Schottky electrode, and an upper JFET portion provided between a sidewall of the first trench and the SBD portion. A junction between surfaces of the Schottky electrode and the SBD portion forms an SBD. A carrier concentration of the SBD portion is lower than the concentration of the first-conductivity-type impurity in the upper JFET portion.

### CROSS REFERENCE TO RELATED APPLICATIONS

This application is based upon and claims the benefit of priority of the prior Japanese Patent Application No. 2023-072786, filed on Apr. 26, 2023, the entire contents of which are incorporated herein by reference.

### BACKGROUND OF THE INVENTION

### 1. Field of the Invention

Embodiments of the invention relate to a silicon carbide semiconductor device.

### 2. Description of the Related Art

Among silicon carbide semiconductor devices using silicon carbide (SiC) as a semiconductor material, a known trench-gate metal oxide semiconductor field effect transistor (MOSFET) having an insulated gate with a three-layer metal-oxide-semiconductor structure is designed to reduce on-resistance by incorporating into the semiconductor substrate (semiconductor chip) of the MOSFET, a Schottky barrier diode (SBD) to suppress operation of a parasitic pn diode (for example, refer to Japanese Laid-Open Patent Publication No. 2020-077664 and M. Okawa et al., “First Demonstration of Short-Circuit Capability for a 1.2 kV SiC SWITCH-MOS”, IEEE Journal of the Electron Devices Society, Vol. 7, (2019), pp. 613-620).

### SUMMARY OF THE INVENTION

According to an embodiment of the present invention, a silicon carbide semiconductor device includes: a semiconductor substrate containing silicon carbide, the semiconductor substrate having a first main surface and a second main surface opposite to each other; a first semiconductor region of a first conductivity type, provided in the semiconductor substrate; a second semiconductor region of a second conductivity type, provided between the first main surface of the semiconductor substrate and the first semiconductor region; a third semiconductor region of the first conductivity type, selectively provided between the first main surface of the semiconductor substrate and the second semiconductor region; a fourth semiconductor region of the first conductivity type, provided between, and in contact with, the second semiconductor region and the first semiconductor region, the fourth semiconductor region having a first-conductivity-type impurity, which is an impurity of the first conductivity type, added thereto, a concentration of the first-conductivity-type impurity being higher than an impurity concentration of the first semiconductor region; a plurality of trenches, each having a predetermined depth from the first main surface of the semiconductor substrate, the plurality of trenches including: a first trench penetrating through the third semiconductor region and the second semiconductor region in a depth direction of the device, and terminating in the fourth semiconductor region, and a second trench penetrating through the second semiconductor region in the depth direction and terminating in the fourth semiconductor region, the second trench being separate from the third semiconductor region; a gate insulating film provided in the first trench; a gate electrode provided in the first trench, on the gate insulating film; a Schottky electrode formed at an inner wall of the second trench, the Schottky electrode being in contact with the fourth semiconductor region; a first electrode electrically connected to the second semiconductor region and the third semiconductor region, the first electrode being embedded in the second trench and in contact with the Schottky electrode; and a second electrode electrically connected to the second main surface of the semiconductor substrate. The fourth semiconductor region includes: a Schottky barrier diode (SBD) portion of the first conductivity type, formed at a sidewall of the second trench and in contact with the Schottky electrode, and an upper junction field effect transistor (JFET) portion of the first conductivity type, provided between a sidewall of the first trench and the SBD portion. A junction between a surface of the Schottky electrode and a surface of the SBD portion forms an SBD. A carrier concentration of the SBD portion is lower than the concentration of the first-conductivity-type impurity added to the upper JFET portion.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to a first embodiment.

FIG. 2 is a characteristics diagram showing results of simulation of IV waveforms during operation of built-in diodes of the silicon carbide semiconductor device according to the first embodiment.

FIG. 3 is a characteristics diagram showing results of simulation of a relationship between specific on-resistance and concentration of an n-type impurity of SBD portions of the silicon carbide semiconductor device according to the first embodiment.

FIG. 4 is a characteristics diagram showing results of simulation of a relationship between the concentration of the n-type impurity of the SBD portions of the silicon carbide semiconductor device according to the first embodiment and SBD leakage current density.

FIG. 5 is a characteristics diagram showing results of simulation of a relationship between the concentration of the n-type impurity of the SBD portions of the silicon carbide semiconductor device according to the first embodiment and current density at an inflection point.

FIG. 6 is a characteristics diagram showing results of simulation of a relationship between the SBD leakage current density and a width of the SBD portions of the silicon carbide semiconductor device according to the first embodiment.

FIG. 7 is a characteristics diagram showing results of simulation of a relationship between the current density at the inflection point and the width of the SBD portions of the silicon carbide semiconductor device according to the first embodiment.

FIG. 8 is a cross-sectional view depicting a structure of a silicon carbide semiconductor device according to a second embodiment.

FIG. 9 is a characteristics diagram showing a relationship between temperature and an ionization rate of aluminum for the silicon carbide semiconductor device according to the second embodiment.

FIG. 10 is a characteristics diagram showing a relationship between device temperature and compensated n-type impurity concentration for the silicon carbide semiconductor device according to the second embodiment.

FIG. 11 is a characteristics diagram showing results of simulation of temperature characteristics of the ionization rate of the p-type impurity.

FIG. 12 is a cross-sectional view depicting a structure of a silicon carbide semiconductor device of a reference example.

### DETAILED DESCRIPTION OF THE INVENTION

First, problems associated with the conventional techniques are discussed. Short-circuit withstand capability (time from a load short-circuit until device breakdown) of the MOSFET having a built-in SBD is significantly lower as compared to the short-circuit withstand capability of a normal MOSFET free of an SBD (refer to M. Okawa et al., “First Demonstration of Short-Circuit Capability for a 1.2 kV SiC SWITCH-MOS”). As disclosed in Japanese Laid-Open Patent Publication No. 2020-077664, while a Schottky barrier height (Schottky barrier) of the built-in SBD is increased to improve the short-circuit withstand capability, due to adverse effects of etching damage during trench formation, Fermi level pinning (phenomenon in which the Fermi level becomes fixed as if pinned to a specific energy position) occurs at an interface of a Schottky junction (metal-semiconductor interface) formed along an inner wall of a trench embedded with the SBD, and there is concern that short-circuit withstand capability may vary due to band arrangement of the metal-semiconductor interface changing and the Schottky barrier height varying.

Embodiments of a silicon carbide semiconductor device according to the present invention is described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

When a MOSFET is used as, for example, a switching element (upper and lower arms) of a bridge-type inverter circuit, a Schottky barrier diode (SBD) built into a single semiconductor substrate having the MOSFET suppresses operation of a parasitic pn diode of the MOSFET during a dead-time for preventing the upper and lower arms from turning on concurrently when the upper and lower arms are repeatedly turned off and on alternately, whereby suppression of degradation of forward characteristics of the parasitic pn diode and reduction of reverse recovery loss are realized. Further, operation of a parasitic pn diode of the MOSFET is suppressed by the built-in SBD, whereby reduction of on-resistance is realized.

First, a reference example of a trench-gate-type MOSFET in which an SBD is built into a single semiconductor substrate having the trench-gate-type MOSFET is described. FIG. 12 is a cross-sectional view depicting a structure of a silicon carbide semiconductor device of the reference example. A silicon carbide semiconductor device 110 of the reference example depicted in FIG. 12 is a trench-gate-type MOSFET in which, multiple trenches 107 are provided in a semiconductor substrate 130, at a front surface of the semiconductor substrate 130; and the trenches 107 include trenches (hereinafter, gate trenches) 107a in which gate electrodes 109 are embedded via gate insulating films 108 and remaining trenches (hereinafter, Schottky trenches) 107b excluding the gate trenches 107a and in which SBDs (hereinafter, trench SBDs) 120 are embedded.

The semiconductor substrate 130 is formed by sequentially forming silicon carbide layers 132, 133 on an n⁺-type starting substrate 131 constituting an n⁺-type drain region 101, the silicon carbide layers 132, 133 being formed by epitaxial growth and constituting, respectively, an n⁻-type drift region 102 and a p-type base region 104. The trenches 107 are provided in a stripe pattern extending in a first direction X parallel to the front surface of the semiconductor substrate 130. The gate trenches 107a and the Schottky trenches 107b are disposed repeatedly alternating with one another in a second direction Y parallel to the front surface of the semiconductor substrate 130 and orthogonal to the first direction X.

The gate trenches 107a penetrate through n⁺-type source regions 105 and the p-type base region 104 from the front surface of the semiconductor substrate 130 in a depth direction Z and reach n-type current spreading regions 103. In the gate trenches 107a, the gate electrodes 109 are provided via the gate insulating films 108. The Schottky trenches 107b penetrate through p⁺⁺-type contact regions 106 and the p-type base region 104 from the front surface of the semiconductor substrate 130 in the depth direction Z and reach the n-type current spreading regions 103. Schottky electrodes 117 are selectively provided along sidewalls of the Schottky trenches 107b. In the Schottky trenches 107b, a source electrode 114 is embedded on the Schottky electrodes 117.

Between the front surface of the semiconductor substrate 130 (main surface thereof facing the silicon carbide layer 133 of a p-type) and the p-type base region 104, the n⁺-type source regions 105 and the p⁺⁺-type contact regions 106 are each selectively provided in contact with the p-type base region 104. Between the p-type base region 104 and the n⁻-type drift region 102, the n-type current spreading regions 103 and p⁺-type regions 111 are each selectively provided. The n-type current spreading regions 103 are provided between the p⁺-type regions 111 that are adjacent to one another, the n-type current spreading regions 103 being in contact with the p⁺-type regions 111.

Each of the n-type current spreading regions 103 has an upper surface (surface facing the n⁺-type source regions 105) in contact with the p-type base region 104 and a lower surface (surface facing the n⁺-type drain region 101) in contact with the n⁻-type drift region 102. Each of the n-type current spreading regions 103 has a first end extending in the second direction Y and reaching one of the gate trenches 107a and a second end extending in the second direction Y and reaching one of the Schottky trenches 107b. The n-type current spreading regions 103 are in contact with the gate insulating films 108 at sidewalls of the gate trenches 107a. The n-type current spreading regions 103 are in contact with the Schottky electrodes 117 at the sidewalls of the Schottky trenches 107b.

In each of the n-type current spreading regions 103, at least a portion (hereinafter, upper JFET portion) 103a thereof between the trenches 107 adjacent thereto is doped with nitrogen (N) of a concentration of about 1×10¹⁷/cm³ to reduce junction FET (JFET) resistance. The p⁺-type regions 111, at deep positions closer to the n⁺-type drain region 101 than are bottoms of the trenches 107, are apart from the p-type base region 104 and in contact with the n-type current spreading regions 103. The p⁺-type regions 111 are provided facing the bottoms of the trenches 107, respectively.

An interlayer insulating film 112 is provided in an entire area of the front surface of the semiconductor substrate 130 so as to cover the gate electrodes 109. The source electrode 114, at the front surface of the semiconductor substrate 130, is electrically connected to the n⁺-type source regions 105 and the p⁺⁺-type contact regions 106 via ohmic electrodes 113. The source electrode 114, at inner walls of the Schottky trenches 107b, is in contact with the p-type base region 104 and the p⁺⁺-type contact regions 106 and is electrically connected to the n-type current spreading regions 103 via the Schottky electrodes 117. Drain electrodes 115, 116 are provided at a back surface (back surface of the n⁺-type starting substrate 131) of the semiconductor substrate 130.

The trench SBDs 120 are diodes that use rectification of Schottky barriers formed by junctions between surfaces of the upper JFET portions 103a and surfaces of the Schottky electrodes 117 on the sidewalls of the Schottky trenches 107b; the Schottky barrier are formed along the sidewalls of the Schottky trenches 107b. The trench SBDs 120 have a function of suppressing operation of parasitic pn diodes of the MOSFET by conducting sooner than the parasitic pn diodes (body diodes) formed by pn junctions between the p-type base region 104, the p⁺-type regions 111, the n⁻-type drift region 102, and the n-type current spreading regions 103 of the MOSFET.

Nonetheless, in the silicon carbide semiconductor device 110 described (MOSFET having the built-in trench SBDs 120), current flowing between a drain and source flows into a load (load turned off and on by the MOSFET) connected to a circuit and generates load voltage. In this state, when load short-circuit occurs in the MOSFET while still in the on-state, drain current Id flows and a drain-source voltage Vds is applied from a voltage source of the circuit. As a result, short-circuit current flows from the n⁺-type drain region 101 and through the n-type drift region 102 and the n-type current spreading regions 103 in a direction to the gate electrodes 109, whereby a rise in temperature occurs in the path of the short-circuit current.

When device temperature (temperature of the semiconductor substrate 130) rises due to short-circuit current, even when the MOSFET is turned off, leakage current flows from the n⁺-type drain region 101 and through the n-type drift region 102 and the n-type current spreading regions 103 to the trench SBDs 120. Leakage current flowing through the trench SBDs 120 increases due to thermoelectric field emission and a rise in temperature occurs in the path of the leakage current, which leads to thermal breakdown of the MOSFET. Japanese Laid-Open Patent Publication No. 2020-077664 discloses that the Schottky barrier height between a metal layer and a drift layer is set to be in a range of 1.76 eV to 3.10 eV, whereby leakage current due to thermoelectric field emission accompanying a rise in temperature during a load short-circuit is reduced.

International Publication No. WO 2022/244749 discloses that for a normal MOSFET free of a built-in SBD, temperature dependency of the ionization rate of aluminum (Al), which is a p-type impurity co-doped (added) to an n-type upper JFET portion, is utilized to reduce carrier concentration of the upper JFET portion during high temperatures caused by load short-circuit, whereby short-circuit current is suppressed. M. Okawa et al. disclose that short-circuit withstand capability (time from load short-circuit until device breakdown) of the trench-gate-type MOSFET having a built-in SBD is 6.0 us and is as low as 60% of the short-circuit withstand capability (=10.0 μs) of a normal MOSFET free of a built-in SBD.

Krishnaswami, et al., “A Study on the Reliability and Stability of High Voltage 4H-SiC MOSFET Devices”, Materials Science Forum, Volumes 527-529, (2006), pp. 1313-1316 disclose that for a normal MOSFET free of a built-in SBD, when a difference (=Nd−Na) of donor concentration Nd and acceptor concentration Na in the upper JFET portion increases, electric field applied to the gate insulating films when the MOSFET is off increases at locations where gate insulating films and the upper JFET portion contact each other. T. Kimoto and J. A. Cooper, “Fundamentals of Silicon Carbide Technology: Growth, Characterization, Devices and Applications”, November 2014, Wiley-IEEE Press, pp. 487 disclose that for an SBD formed at a junction between surfaces of a metal layer and an n-type silicon carbide layer, the lower is a concentration of an n-type impurity in the n-type silicon carbide layer, the easier a depletion layer spreads from the junction between the surfaces of the metal layer and the n-type silicon carbide layer when a reverse bias is applied, whereby electric field strength of the junction between the surfaces decreases and thus, leakage current flowing through an SBD is reduced.

Through the earnest research by the inventor, it was found that in the silicon carbide semiconductor device 110 of the described reference example (MOSFET in which the trench SBDs 120 are built, refer to FIG. 12), there is concern that due to adverse effects of etching damage of inner walls of the Schottky trenches 107b, Fermi level pinning occurs at the interfaces (metal-semiconductor interfaces) of the Schottky junctions of the trench SBDs 120 and Schottky barrier height varies, whereby short-circuit withstand capability varies. In the present embodiments, incorporating SBDs and reducing on-resistance while reducing leakage current flowing in SBDs and enhancing short-circuit withstand capability are given as problems to be solved.

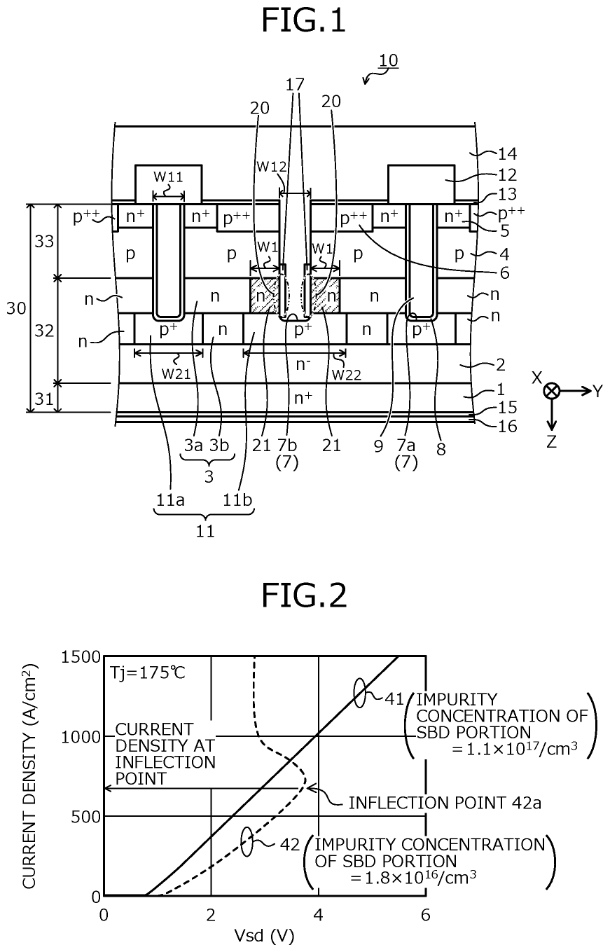

A structure of a silicon carbide semiconductor device according to a first embodiment is described using a cross-sectional view in FIG. 1. The silicon carbide semiconductor device 10 depicted in FIG. 1 is a trench-gate-type MOSFET in which in a semiconductor substrate 30 containing silicon carbide (SiC) as a semiconductor material, multiple trenches 7 are provided in the semiconductor substrate 30, at a front surface thereof, the trenches 7 including trenches (gate trenches: first trenches) 7a in which gate electrodes 9 are embedded via gate insulating films 8, and remaining trenches (Schottky trenches: second trenches) 7b excluding the gate trenches 7a, in which SBDs (trench SBDs) 20 are embedded.

FIG. 1 depicts two unit cells (constituent units of a device) among multiple adjacent unit cells each disposed in an active region and having an identical structure (trench gate structure). FIG. 1 does not depict an edge termination region that surrounds a periphery of the active region (similarly with FIG. 2). The active region is a region through which current flows when the MOSFET is in an on-state. The edge termination region is a region between the active region and a side surface of the semiconductor substrate (semiconductor chip) 30, and in the edge termination region, a voltage withstanding structure is disposed that mitigates electric field of a front side of the semiconductor substrate 30 and sustains a breakdown voltage. The breakdown voltage is a voltage limit at which no malfunction or destruction of a semiconductor device occurs.

The semiconductor substrate 30 is formed by sequentially forming, by epitaxial growth on a front surface of an n⁺-type starting substrate 31 containing silicon carbide as a semiconductor material, silicon carbide layers 32, 33 constituting an n-type drift region (first semiconductor region) 2 and p-type base region (second semiconductor region) 4, respectively. The semiconductor substrate 30 has, as a front surface, a first main surface having the p-type silicon carbide layer 33 and, as a back surface, a second main surface (back surface of the n⁺-type starting substrate 31) having the n⁺-type starting substrate 31. The n⁺-type starting substrate 31 constitutes an n⁺-type drain region 1. In the active region, the trench gate structure is provided in the semiconductor substrate 30, at the front surface thereof.

The trench gate structure is configured by the p-type base region 4, n⁺-type source regions (third semiconductor regions) 5, p⁺⁺-type contact regions 6, the gate trenches 7a, the gate insulating films 8, and the gate electrodes 9. Each of the trenches 7, for example, is provided in a stripe shape extending in the first direction X parallel to the front surface of the semiconductor substrate 30. The gate trenches 7a and the Schottky trenches 7b are disposed repeatedly alternating with one another in the second direction Y parallel to the front surface of the semiconductor substrate 30 and orthogonal to the first direction X.

The gate trenches 7a penetrate through the n⁺-type source regions 5 and the p-type base region 4 in the depth direction Z from the front surface of the semiconductor substrate 30 and terminate in later-described n-type current spreading regions (fourth semiconductor regions) 3. Each of the n-type current spreading regions 3 includes one each of later-described upper JFET portions 3a, lower JFET portions 3b, and SBD portions 21. In the gate trenches 7a, the gate electrodes 9 are provided via the gate insulating films 8, respectively. The Schottky trenches 7b penetrate through the p⁺⁺-type contact regions 6 and the p-type base region 4 in the depth direction Z from the front surface of the semiconductor substrate 30 and terminate in the p-type regions 11. Along sidewalls of the Schottky trenches 7b, Schottky electrodes 17 are selectively provided. A source electrode (first electrode) 14 is embedded in the Schottky trenches 7b, on the Schottky electrodes 17.

The n⁺-type source regions 5 and the p⁺⁺-type contact regions 6 are each selectively provided between the front surface of the semiconductor substrate 30 and the p-type base region 4 and are in contact with the p-type base region 4. The p⁺⁺-type contact regions 6 are diffused regions formed by ion-implanting a p-type impurity (acceptor) such as, for example, aluminum (Al), in the p-type silicon carbide layer 33. The n⁺-type source regions 5 and the p⁺⁺-type contact regions 6 are exposed at the front surface of the semiconductor substrate 30. Being exposed at the front surface of the semiconductor substrate 30 means being in contact with ohmic electrodes 13 at the front surface of the semiconductor substrate 30.

The n⁺-type source regions 5 are in contact with the gate insulating films 8 at sidewalls of the gate trenches 7a. The n⁺-type source regions 5 are provided apart from the Schottky trenches 7b. The p⁺⁺-type contact regions 6 are provided apart from the gate trenches 7a. The p⁺⁺-type contact regions 6 are in contact with the source electrode 14 at the sidewalls of the Schottky trenches 7b. The p⁺⁺-type contact regions 6 may be omitted. In this instance, instead of the p⁺⁺-type contact regions 6, the p-type base region 4 is exposed at the front surface of the semiconductor substrate 30. A portion of the p-type silicon carbide layer 33 excluding the n⁺-type source regions 5 and the p⁺⁺-type contact regions 6 constitutes the p-type base region 4.

Between the p-type base region 4 and the n-type drift region 2, the n-type current spreading regions 3 and p⁺-type regions 11 are each selectively provided. The n-type current spreading regions 3 constitute a so-called current spreading layer (CSL) that reduces carrier spreading resistance. The n-type current spreading regions 3 are diffused regions formed in the n⁻-type silicon carbide layer 32 by ion implantation. Each of the n-type current spreading regions 3 has a portion (hereinafter, upper JFET portion) 3a closer to the n⁺-type source regions 5 than are the p⁺-type regions 11, a portion (hereinafter, lower JFET portion) 3b adjacent to the p⁺-type regions 11 in the second direction Y, and one of the SBD portions 21 having concentration of an n-type impurity lower than that of the other portions. The concentrations of the n-type impurity of the upper JFET portions 3a, the lower JFET portions 3b, and the SBD portions 21 are higher than the concentration of the n-type impurity of the n-type drift region 2.

Each of the upper JFET portions 3a has an upper surface (surface facing the n⁺-type source regions 5) in contact with the p-type base region 4 and a lower surface (surface facing the n⁺-type drain region 1) in contact with a corresponding one of the lower JFET portions 3b, a corresponding one of later-described first high-concentration regions 11a, and a corresponding one of second high-concentration regions 11b. Each of the upper JFET portions 3a has a first end and a second end extending in the second direction Y, the first end reaching one of the gate trenches 7a and the second end reaching one of the SBD portions 21. The upper JFET portions 3a are in contact with the gate insulating films 8 at the sidewalls of the gate trenches 7a. Each of the lower JFET portions 3b is a portion between any one of the first high-concentration regions (fifth semiconductor regions) 11a and an adjacent one of the second high-concentration regions (sixth semiconductor regions) 11b, is in contact with these regions in the second direction Y, and has a lower surface in contact with the n⁻-type drift region 2. The upper JFET portions 3a and the lower JFET portions 3b are doped with, as a dopant (impurity added to a semiconductor), nitrogen (N), which is an n-type impurity (donor: first-conductivity-type impurity).

The upper JFET portions 3a and the lower JFET portions 3b have a concentration of the n-type impurity (nitrogen concentration) that is about, for example, 1×10¹⁷/cm³. Preferably, the upper JFET portions 3a and the lower JFET portions 3b may have a concentration of the n-type impurity, for example, in a range of about 7×10¹⁶/cm³ to 7×10¹⁷/cm³. A value at least equal to the lower limit described above (=7×10¹⁶/cm³) is set, whereby increases in the on-resistance may be prevented. Further, a value not more than the upper limit described above (=7×10¹⁷/cm³) is set, whereby with consideration of long-term reliability, electric field applied to the gate insulating films 8 when the MOSFET is off may be set to be not more than 3 MV/cm (refer to Krishnaswami, et al., “A Study on the Reliability and Stability of High Voltage 4H-SiC MOSFET Devices”, Materials Science Forum, Volumes 527-529, (2006), pp. 1313-1316).

The SBD portions 21 are provided between the upper JFET portions 3a and the Schottky trenches 7b. Each of the SBD portions 21 has an upper surface in contact with the p-type base region 4 and a lower surface in contact with only the second high-concentration regions 11b. The SBD portions 21 do not contact (are apart from) the lower JFET portions 3b. The SBD portions 21 have first ends in the second direction Y, in contact with the upper JFET portions 3a, and second ends in the second direction Y, reaching the Schottky trenches 7b. The SBD portions 21 are SiC semiconductor regions (hatched portions) in contact with the Schottky electrodes 17 at the sidewalls of the Schottky trenches 7b and forming later-described trench SBDs 20. The SBD portions 21 have a function of spreading a depletion layer in the semiconductor substrate 30, from surfaces of the SBD portions 21 forming junctions with the Schottky electrodes 17 during load short-circuit and thereby suppressing leakage current flowing through the trench SBDs 20.

The SBD portions 21 are doped with, as a dopant, nitrogen, which is an n-type impurity (donor: first-conductivity-type impurity). A concentration of the n-type impurity (nitrogen concentration) of the SBD portions 21 is in a range of 10% to less than 100% of the concentration of the n-type impurity of the upper JFET portions 3a. A carrier concentration of the SBD portions 21 is lower than the concentration of the n-type impurity of the upper JFET portions 3a. The carrier concentration is the concentration of charge carriers (charged particles) that are activated and carry electrical conductivity, among impurities (dopants) added to the semiconductor. Nitrogen, as an n-type impurity, is activated nearly 100% in the silicon carbide semiconductor over an expected temperature range and emits electrons, which are charge carriers of an n-type semiconductor. Thus, while the carrier concentration of the SBD portions 21, which are an n-type, is the concentration of activated electrons, the carrier concentration of the SBD portions 21 may be approximated by the concentration of nitrogen, which is an n-type impurity.

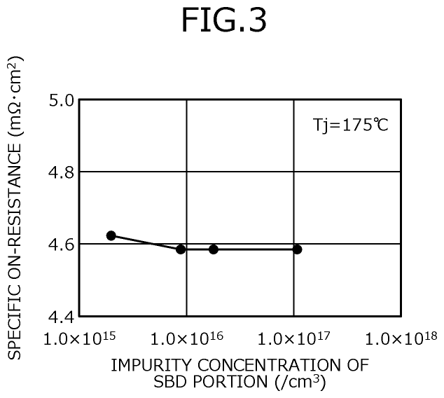

A width W1 of each of the SBD portions 21 is assumed to be in a range such that the entire lower surface of each of the SBD portions 21 is in contact with a corresponding one of the second high-concentration regions 11b and so that the SBD portions 21 are not in contact with (are apart from) the lower JFET portions 3b. The width W1 of each of the SBD portions 21 is a dimension in the second direction Y, from a surface thereof forming a junction with a corresponding one of the Schottky electrodes 17 to an interface thereof with a corresponding one of the upper JFET portions 3a. The SBD portions 21 are apart from the lower JFET portions 3b, whereby the SBD portions 21 are not on paths of a main current flowing through channels when the MOSFET is in operation (when the MOSFET is on). Thus, increases in the on-resistance of the MOSFET may be suppressed (refer to later-described FIG. 3).

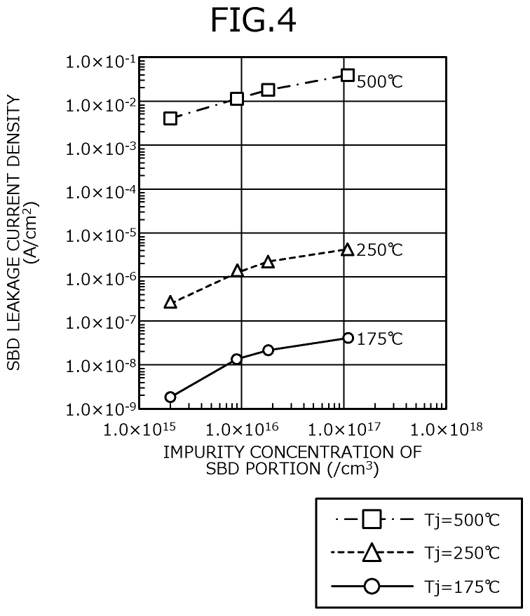

On the other hand, during load (load turned off and on by the MOSFET) short-circuit, the SBD portions 21 become a path of leakage current flowing through the trench SBDs 20. For example, in the MOSFET (the silicon carbide semiconductor device 110: refer to FIG. 12) of the reference example, when device temperature (for example, about 250 degrees C. to 500 degrees C.) rises due to load short-circuit, leakage current flowing through the trench SBDs 120 increases after the MOSFET turns off, in the first embodiment, as described above; however, the concentration of the n-type impurity of the SBD portions 21 are set relatively low in the n-type current spreading regions 3, whereby conduction resistance of the trench SBDs 20 increases and thus, leakage current flowing through the trench SBDs 20 during load short-circuit may be reduced (refer to later-described FIG. 4).

The lower the concentration of the n-type impurity of the SBD portions 21 is set, the higher is the effect of reducing the leakage current that flows through the trench SBDs 20 during load short-circuit. As a result, in the MOSFET (the silicon carbide semiconductor device 10), generation of heat (temperature increase of the semiconductor substrate 30) after the gates are turned off (after voltage applied to the gate electrodes 9 becomes less than a gate threshold voltage) is suppressed and short-circuit withstand capability is enhanced. On the other hand, the lower the concentration of the n-type impurity of the SBD portions 21 is set, the greater is the conduction resistance of the trench SBDs 20. As a result, before the trench SBDs 20 conduct, parasitic pn diodes (body diodes) of the MOSFET become operable by a relatively low current density and, degradation of forward characteristics of parasitic pn diodes and increases in reverse recovery loss occur.

The conduction resistance of the trench SBDs 20 is a resistance value (differential resistance) at a conduction (start of operation) point of IV (current-voltage) characteristics of the trench SBDs 20. The parasitic pn diodes of the MOSFET are built-in diodes formed in the semiconductor substrate 30 by pn junctions between the p-type base region 4, the p⁺-type regions 11 (the first and second high-concentration regions 11a, 11b), the n⁻-type drift region 2, and the n-type current spreading regions 3 (the upper JFET portions 3a, the lower JFET portions 3b, the SBD portions 21). Forward current density that starts operation (conduction) of the parasitic pn diodes of the MOSFET may be obtained based on the IV characteristics of the built-in diodes of the semiconductor substrate 30. Results of simulation of IV waveforms of the internal diodes of the semiconductor substrate 3 are depicted in FIG. 2.

FIG. 2 is a characteristics diagram showing results of simulation of IV waveforms during operation of the built-in diodes (internal diodes) of the silicon carbide semiconductor device according to the first embodiment. In FIG. 2, a horizontal axis represents voltage (source-drain voltage Vsd) that is positive with respect to a drain electrode 15 and applied to the source electrode 14; the voltage corresponds to forward voltage of the internal diodes. In FIG. 2, a vertical axis corresponds to forward current density of the internal diodes. FIG. 2 depicts a IV waveform 41 (solid line) of the internal diodes in an instance in which the concentration of the n-type impurity of the SBD portions 21 (in FIG. 2, depicted as concentration of the SBD portions) is assumed to be 1.1×10¹⁷/cm³ and an IV waveform 42 (dashed line) of the internal diodes in an instance in which the concentration of the n-type impurity of the SBD portions 21 is assumed to be 1.8×10¹⁶/cm³. The IV waveform 41 exhibits characteristics (comparison example) of a structure (i.e., the silicon carbide semiconductor device 110 of the reference example in FIG. 12) in which the concentrations of the n-type impurity of the upper JFET portions 3a and the SBD portions 21 are equal to each other.

As depicted in FIG. 2, in an instance in which the concentration of the n-type impurity of the SBD portions 21 is set to be 1.1×10¹⁷/cm³, the IV waveform 41 of the internal diodes exhibits increased forward current density accompanying rises in the forward voltage. On the other hand, it is found that in an instance in which the concentration of the n-type impurity of the SBD portions 21 is reduced to 1.8×10¹⁶/cm³, at a forward current density of about 750 A/cm², the IV waveform 42 of the internal diodes is curved, operation of the parasitic pn diodes starts, minority carriers (holes) are injected into the upper JFET portions 3a, the lower JFET portions 3b and the n-type drift region 2, the forward current density of the internal diodes increases, and at an inflection point 42a of the forward current density, conduction resistance of the internal diodes decreases (conductivity modulation).

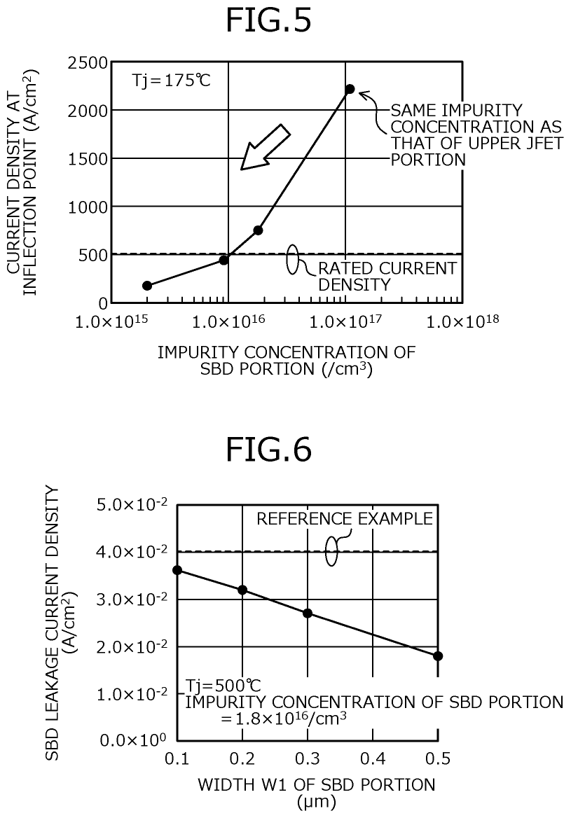

Hereinafter, the forward current density at the inflection point of the IV waveform of the internal diodes of the MOSFET is referred to as current density at the inflection point and is regarded as an index indicating ease of operation of the parasitic pn diodes. The current density at the inflection point of the IV waveform of the internal diodes of the MOSFET is at least the rated current density of the MOSFET (for example, about 500 A/cm²) or greater. Based on the constraints above, preferably, the concentration of the n-type impurity of the SBD portions 21, for example, may be in a range of about 1×10¹⁶/cm³ to less than 1×10¹⁷/cm³ (refer to later-described FIG. 5). Here, while the device temperature (temperature of the semiconductor substrate 30) was assumed to be 175 degrees C., a relationship between the concentration of the n-type impurity of the SBD portions 21 and the forward current density of the internal diodes exhibits a same trend independent of device temperature (refer to later-described FIG. 4).

The p⁺-type regions 11 are diffused regions formed in the n-type silicon carbide layer 32 by ion implantation of a p-type impurity such as, for example, aluminum. The p⁺-type regions 11, at a non-depicted portion, are electrically connected to the source electrode 14, deplete when the MOSFET is off (or causes the n-type current spreading regions 3 to deplete or both), and have a function of mitigating electric field applied to the bottoms of the gate trenches 7a. The p⁺-type regions 11 are provided apart from the p-type base region 4, at deep positions closer to the n⁺-type drain region 1 than are the bottoms of the trenches 7. The p⁺-type regions 11 are provided at the bottoms of the trenches 7, respectively.

In particular, the p⁺-type regions 11 are constituted by the first high-concentration regions 11a beneath the gate trenches 7a and the second high-concentration regions 11b beneath the Schottky trenches 7b. Each of the first high-concentration regions 11a has a width (width in the second direction Y) W21 that is wider than a width (width in the second direction Y) W11 of each of the gate trenches 7a; and each of the first high-concentration regions 11a protrudes in a direction that is parallel to the second direction Y and away from the sidewalls of a corresponding one of the gate trenches 7a. Each of the second high-concentration regions 11b has a width (width in the second direction Y) W22 wider than a width (width in the second direction Y) W12 of each of the Schottky trenches 7b; and each of the second high-concentration regions 11b protrudes in a direction that is parallel to the second direction Y and away from the sidewalls of a corresponding one of the Schottky trenches 7b.

A width of each of the second high-concentration regions 11b protruding in a direction parallel to the second direction Y and away from the sidewalls of the Schottky trenches 7b is wider than the width W1 of each of the SBD portions 21. In other words, each of the second high-concentration regions 11b is in contact with the entire lower surface of a corresponding one of the SBD portions 21 and is in contact with a corresponding one of the upper JFET portions 3a. The second high-concentration regions 11b are in contact with the entire lower surface of each of the SBD portions 21, whereby the SBD portions 21 and the lower JFET portions 3b are disposed apart from one another. The width W22 of each of the second high-concentration regions 11b may be wider than the width W21 of each of the first high-concentration regions 11a or may be equal to the width W21 of each of the first high-concentration regions 11a. In FIG. 1, a relationship of the width W22 of each of the second high-concentration regions 11b with the width W1 of each of the SBD portions 21 and the width W12 of each of the Schottky trenches 7b is expressed as W22>2. W1+W12.

A portion of the n-type silicon carbide layer 32 excluding the n-type current spreading regions 3 and the p⁺-type regions 11 constitutes the n-type drift region 2. An interlayer insulating film 12 is provided in an entire area of the front surface of the semiconductor substrate 30 so as to cover the gate electrodes 9. The interlayer insulating film 12 has contact holes exposing the n⁺-type source regions 5, the p⁺⁺-type contact regions 6, and the Schottky trenches 7b. The ohmic electrodes 13 are in ohmic contact with the front surface of the semiconductor substrate 30, at the contact holes of the interlayer insulating film 12. The ohmic electrodes 13 are constituted by, for example, nickel silicide (NixSiy, where, x, y are positive numbers) electrodes.

The source electrode 14 is provided in substantially the entire area of the front surface of the semiconductor substrate 30 in the active region so as to be embedded in the contact holes of the interlayer insulating film 12 and the Schottky trenches 7b. The source electrode 14 is electrically connected to the n⁺-type source regions 5 and the p⁺⁺-type contact regions 6 at the front surface of the semiconductor substrate 30 via the ohmic electrodes 13. The source electrode 14 is in contact with the p-type base region 4 and the p⁺⁺-type contact regions 6 at the sidewalls of the Schottky trenches 7b and is electrically connected to the n-type current spreading regions 3 (the upper JFET portions 3a, the lower JFET portions 3b, the SBD portions 21) via the Schottky electrodes 17.

Between the source electrode 14 and the sidewalls of the Schottky trenches 7b, the Schottky electrodes 17 are provided along the sidewalls of the Schottky trenches 7b. The Schottky electrodes 17 are in contact with the SBD portions 21, at the sidewalls of the Schottky trenches 7b. The Schottky electrodes 17 may extend from the sidewalls to the bottoms of the Schottky trenches 7b. The Schottky electrodes 17 may be in contact with the second high-concentration regions 11b, the p-type base region 4, and the p⁺⁺-type contact regions 6, at the inner walls of the Schottky trenches 7b. A material of the Schottky electrodes 17 is, for example, titanium (Ti).

The front surface of the semiconductor substrate 30 is protected by a passivation film. A portion of the source electrode 14 exposed by an opening of the passivation film constitutes a source electrode pad. The drain electrode (second electrode) 15 is provided in an entire area of the back surface (the back surface of the n⁺-type starting substrate 31) of the semiconductor substrate 30. The drain electrode 15 is in ohmic contact with the n⁺-type drain region 1 (the n⁺-type starting substrate 31) and connected to the n⁺-type drain region 1. A drain electrode pad 16 is provided on the entire surface of the drain electrode 15.

The trench SBDs 20 are diodes using rectification of Schottky barriers formed by junctions between surfaces of the SBD portions 21 and surfaces of the Schottky electrodes 17 on the sidewalls of the Schottky trenches 7b; the trench SBDs 20 are formed along the sidewalls of the Schottky trenches 7b. The trench SBDs 20 conduct sooner than parasitic pn diodes (body diodes) formed by pn junctions between the p-type base region 4, the p⁺-type regions 11 (the first and second high-concentration regions 11a, 11b), the n-type current spreading regions 3 (the upper JFET portions 3a, the lower JFET portions 3b, the SBD portions 21), and the n-type drift region 2 of the MOSFET; the trench SBDs 20 have a function of suppressing operation of the parasitic pn diodes of the MOSFET.

Operation of the silicon carbide semiconductor device 10 is described. When voltage (the drain-source voltage Vds: forward voltage of the MOSFET) that is positive with respect to the source electrode 14 is applied to the drain electrode 15 and voltage (gate voltage) at least equal to the gate threshold voltage is applied to the gate electrodes 9 (during steady operation), a channel (n-type inversion layer) is formed at portions of the p-type base region 4 along the sidewalls of the gate trenches 7a. As a result, a main current (drift current) flows from the n⁺-type drain region 1, through the channel, to the n⁺-type source regions 5, and the MOSFET (the silicon carbide semiconductor device 10) turns on.

On the other hand, when the drain-source voltage Vds is applied and the gate voltage is less than the gate threshold voltage, the pn junctions (main junctions of the MOSFET) between the p-type base region 4, the p⁺-type regions 11, the n-type current spreading regions 3, and the n⁻-type drift region 2 are reverse biased, whereby the main current stops flowing and the MOSFET maintains the off-state. Further, due to a depletion layer spreading from the main junctions of the MOSFET, the p⁺-type regions 11 (or the n-type current spreading regions 3, or both) are depleted and electric field applied to the gate insulating films 8 at the inner walls of the gate trenches 7a is mitigated.

During load short-circuit, the SBD portions 21 having a lowered impurity concentration facilitate the spreading of a depletion layer in the n-type current spreading regions 3, from the junctions between the surfaces (Schottky junction surfaces) of the Schottky electrodes 17 and the surfaces of the SBD portions 21, and the electric field strength at the Schottky junction surfaces decreases. Thus, the electric field applied to the trench SBDs 20 is mitigated and leakage current flowing through the trench SBDs 20 may be reduced. The concentration of the n-type impurity of the SBD portions 21 may be reproduced and controlled by the dose of the ion-implanted n-type impurity and thus, controllability of the conduction resistance of the trench SBDs 20 is high.

Further, during forward bias of the internal diodes, the trench SBDs 20 conduct sooner than the parasitic pn diodes, by a voltage lower than that causing the parasitic pn diodes to conduct. Thus, the parasitic pn diodes of the MOSFET do not operate. As a result, reverse recovery loss and degradation of forward characteristics due to operation of the parasitic pn diodes of the MOSFET do not occur.

A method of manufacturing the silicon carbide semiconductor device 10 is described. First, the n-type silicon carbide layer 32, which is doped with, for example, nitrogen and constitutes the n⁻-type drift region 2, is epitaxially grown (deposited) on the front surface of the n⁺-type starting substrate (semiconductor wafer) 31, which constitutes the n⁺-type drain region 1. At this stage, of the n⁻-type silicon carbide layer 32 (i.e., the n⁻-type silicon carbide layer 32 of a predetermined thickness and configuring the semiconductor substrate 30 of a product thickness) depicted in FIG. 1, the n⁻-type silicon carbide layer corresponding to formation regions of the upper JFET portions 3a and the SBD portions 21 is not yet formed.

Next, by photolithography and, for example, selective ion-implantation of a p-type impurity such as aluminum (Al), the first high-concentration regions 11a and the second high-concentration regions 11b are formed in surface regions of the n-type silicon carbide layer 32 so as to be apart from one another and repeatedly alternate with one another in the second direction Y. By photolithography and selective ion-implantation of an n-type impurity such as nitrogen, the n-type lower JFET portions 3b are formed in surface regions of the n-type silicon carbide layer 32, between the first high-concentration regions 11a and the second high-concentration regions 11b adjacent to one another. The concentration of the n-type impurity of the lower JFET portions 3b is, for example, about 1×10¹⁷/cm³.

Further, the thickness of the n⁻-type silicon carbide layer 32 is increased to a predetermined thickness by epitaxial growth. The concentration of the n-type impurity of the epitaxially grown additional portion increasing the thickness of the n⁻-type silicon carbide layer 32 is a concentration of nitrogen (for example, about 1.8×10¹⁶/cm³) corresponding to the concentration of the n-type impurity of the SBD portions 21. Of the n-type silicon carbide layer 32 depicted in FIG. 1, the portion (the n⁻-type silicon carbide layer) increasing the thickness of the n-type silicon carbide layer 32 corresponds to formation regions of the upper JFET portions 3a and the SBD portions 21. Thus, the thickness of the portion increasing the thickness of the n⁻-type silicon carbide layer 32 is set to be a same thickness as that of each of the upper JFET portions 3a and each of the SBD portions 21. At this stage, the entire n⁻-type silicon carbide layer 32 depicted in FIG. 1 has been formed.

Next, an ion implantation mask opened at portions corresponding to formation regions of the upper JFET portions 3a is formed at the surface of the n-type silicon carbide layer 32 by photolithography. Next, by ion-implantation of an n-type impurity, for example, nitrogen, using the ion implantation mask, the upper JFET portions 3a are selectively formed in the portion that increases the thickness of the n-type silicon carbide layer 32, the upper JFET portions 3a being formed at a depth reaching the lower JFET portions 3b. The concentration of the n-type impurity of the upper JFET portions 3a is, for example, about 1×10¹⁷/cm³. Thereafter, the ion implantation mask is removed.

In the portion that increases the thickness of the n-type silicon carbide layer 32, portions covered by the ion implantation mask and thereby, free of implanted ions and having a concentration of the n-type impurity remaining the same as that at the time of the epitaxial growth constitute the SBD portions 21. Ion-implantation of an n-type impurity such as nitrogen for forming the SBD portions 21 may be additionally performed to thereby adjust the concentration of the n-type impurity of the SBD portions 21. In this instance, an ion implantation mask opened at portions corresponding to formation regions of the SBD portions 21 is formed at the surface of the n⁻-type silicon carbide layer 32 and ion-implantation of an n-type impurity is performed using the mask. The sequence in which the upper JFET portions 3a and the SBD portions 21 are formed may be reversed.

Next, the p-type silicon carbide layer 33 doped with, for example, aluminum and constituting the p-type base region 4 is epitaxially grown (deposited) on the n-type silicon carbide layer 32. The p-type silicon carbide layer 33 is in contact with the upper JFET portions 3a and the SBD portions 21 formed in surface regions of the n⁻-type silicon carbide layer 32 beneath the p-type silicon carbide layer 33. By the processes up to here, the semiconductor substrate (semiconductor wafer) 30 in which the silicon carbide layers 32, 33 are sequentially stacked on the n⁺-type starting substrate 31 is fabricated (manufactured).

Next, by photolithography and ion implantation, in regions of the semiconductor substrate 30, at the front surface thereof, the n⁺-type source regions 5 and the p⁺⁺-type contact regions 6 are each selectively formed in the p-type silicon carbide layer 33. In the p-type silicon carbide layer 33, a portion free of implanted ions and having an impurity concentration remaining the same as that at the time of epitaxial growth constitutes the p-type base region 4. Next, a heat treatment for activating the impurities ion-implanted in the silicon carbide layers 32, 33 is performed.

Next, the trenches 7 (the gate trenches 7a and the Schottky trenches 7b) are formed by, for example, dry etching. The gate trenches 7a penetrate through the n⁺-type source regions 5 and the p-type base region 4 from the front surface of the semiconductor substrate 30, reach the upper JFET portions 3a, and face the first high-concentration regions 11a in the depth direction Z. The upper JFET portions 3a may intervene between the bottoms of the gate trenches 7a and the first high-concentration regions 11a or the gate trenches 7a may penetrate through the upper JFET portions 3a in the depth direction Z and terminate in the first high-concentration regions 11a.

The Schottky trenches 7b penetrate through the p⁺⁺-type contact regions 6 and the p-type base region 4 from the front surface of the semiconductor substrate 30, reach the SBD portions 21, and face the second high-concentration regions 11b in the depth direction Z. The SBD portions 21 may intervene between the bottoms of the Schottky trenches 7b and the second high-concentration regions 11b or the Schottky trenches 7b may penetrate through the SBD portions 21 in the depth direction Z and terminate in the second high-concentration regions 11b.

Next, by a general method, the gate insulating films 8 and the gate electrodes 9 thereon are formed in the gate trenches 7a. Next, the interlayer insulating film 12 is formed in the entire area of the front surface of the semiconductor substrate 30. Next, contact holes penetrating through the interlayer insulating film 12 in the depth direction Z and reaching the front surface of the semiconductor substrate 30 are formed. The n⁺-type source regions 5, the p⁺⁺-type contact regions 6, and the Schottky trenches 7b are exposed in the contact holes of the interlayer insulating film 12.

Next, by a general method, the ohmic electrodes 13 in ohmic contact with the n⁺-type source regions 5 and the p⁺⁺-type contact regions 6 are formed in the contact holes of the interlayer insulating film 12. Further, the Schottky electrodes 17 are formed at the sidewalls of the Schottky trenches 7b, the Schottky electrodes 17 being in contact with the SBD portions 21. Thus, the trench SBDs 20 that use the rectification of the Schottky barriers formed by the junctions between the surfaces of the Schottky electrodes 17 and the surfaces of the SBD portions 21 are formed.

Next, the source electrode 14 is formed on the front surface of the semiconductor substrate 30, so as to be embedded in the contact holes of the interlayer insulating film 12 and the Schottky trenches 7b. As a result, in the Schottky trenches 7b, the source electrode 14 is connected to the Schottky electrodes 17. Further, the drain electrode 15 is formed on the back surface of the semiconductor substrate 30 and the drain electrode pad 16 is formed on the drain electrode 15. Thereafter, the semiconductor wafer is diced (cut) into individual chips, whereby the silicon carbide semiconductor device 10 depicted in FIG. 1 is completed.

A relationship between the concentration of the n-type impurity of the SBD portions 21 (refer to FIG. 1) described above and device characteristics of the MOSFET was verified. Results of verification by simulation are shown in FIGS. 3 to 7. In FIGS. 3 to 7, the simulation was performed using a MOSFET having the structure of the silicon carbide semiconductor device 10 according to the first embodiment depicted in FIG. 1. In the MOSFET, the concentrations (1×10¹⁷/cm³) of the n-type impurity of the upper JFET portions 3a and of the lower JFET portions 3b were assumed to be constant.

In FIGS. 3 to 5, the width W1 of each of the SBD portions 21 was set to be 0.5 μm and various characteristics were simulated by varying the concentration of the n-type impurity of the SBD portions 21. In FIGS. 3 to 5, a horizontal axis indicates the concentration of the n-type impurity of the SBD portions 21. In FIG. 3, a vertical axis indicates specific on-resistance of the MOSFET (on-resistance not dependent on the area of the active region). In FIG. 4, a vertical axis indicates the density of leakage current flowing through the trench SBDs 20 (hereinafter, the SBD leakage current density). In FIG. 5, a vertical axis indicates the current density at the inflection point of the IV waveform of the internal diodes of the MOSFET.

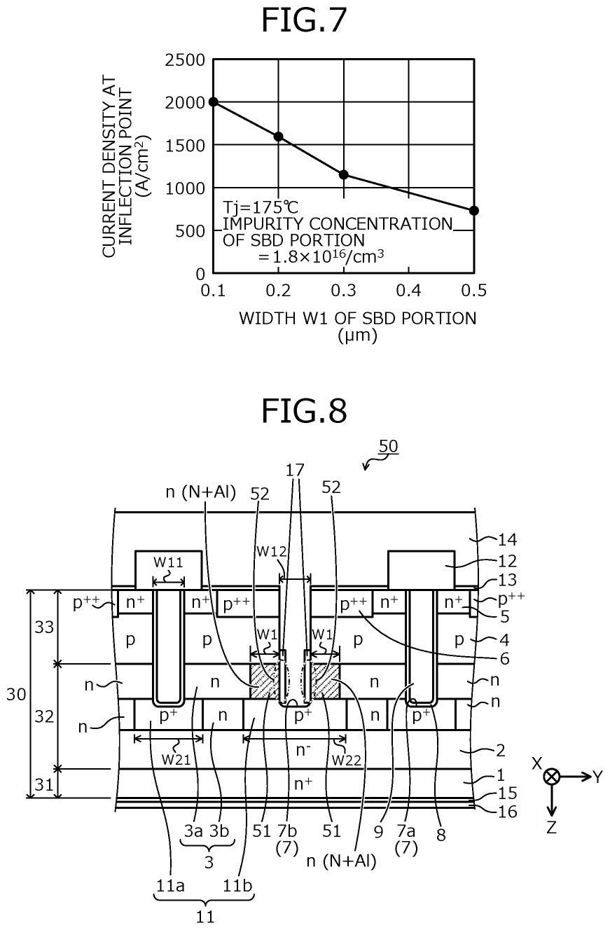

In FIGS. 6 and 7, the concentration of the n-type impurity of the SBD portions 21 was set to be 1.8×10¹⁶/cm³ and various characteristics were simulated by varying the width W1 of the SBD portions 21. In FIGS. 6 and 7, a horizontal axis indicates the width W1 of the SBD portions 21. In FIGS. 6 and 7, vertical axes indicate, respectively, the SBD leakage current density and the current density at the inflection point of the IV waveform of the internal diodes of the MOSFET. In FIG. 3, gate voltage Vg of the MOSFET was set to be 20V. In FIGS. 4 and 6, the gate voltage Vg was set to be 0V and the drain-source voltage Vds was set to be 600V. FIGS. 4 and 6 assume an instance in which high voltage is applied to the MOSFET during load short-circuit.

In FIGS. 3, 5, and 7, device temperature was set to be 175 degrees C. FIG. 4 shows results of simulation when the device temperature was set to be 175 degrees C., 250 degrees C., and 500 degrees C. In FIG. 6, the device temperature was set to be 500 degrees C. The device temperature is a junction temperature Tj at the main junctions (pn junctions) of the MOSFET and corresponds to the temperature of the semiconductor substrate 30. FIGS. 3 to 7 show results of simulation related to a silicon carbide semiconductor to which nitrogen is added; the concentration of the n-type impurity of the SBD portions 21 (nitrogen concentration) is assumed to be substantially equal to the carrier concentration in the semiconductor; and temperature dependency of the forward characteristics of the trench SBDs 20 is assumed to be negligible.

FIG. 3 is a characteristics diagram showing results of simulation of the relationship between the specific on-resistance and the concentration of the n-type impurity of the SBD portions of the silicon carbide semiconductor device 10. From the results shown in FIG. 3, it was confirmed that even when the impurity concentration of the SBD portions 21 is reduced, the specific on-resistance of the MOSFET does not substantially change. Accordingly, a predetermined specific on-resistance of the MOSFET may be set independent of the concentration of the n-type impurity of the SBD portions 21.

FIG. 4 is a characteristics diagram showing results of simulation of a relationship between the concentration of the n-type impurity of the SBD portions of the silicon carbide semiconductor device 10 and the SBD leakage current density. From the results shown in FIG. 4, it was confirmed that by reducing the concentration of the n-type impurity of the SBD portions 21, the SBD leakage current density when the MOSFET is off may be reduced. Further, the higher is the device temperature, the greater is the SBD leakage current density, nonetheless, the tendency of the SBD leakage current density to decrease due to reduction of the impurity concentration of the SBD portions 21 is the same independent of device temperature. Therefore, to reduce the SBD leakage current density, preferably, the impurity concentration of the SBD portions 21 may be reduced.

On the other hand, as described above, in an instance in which the concentration of the n-type impurity of the SBD portions 21 is low, the conduction resistance of the trench SBDs 20 increases and the parasitic pn diodes of the MOSFET easily exceed a threshold voltage and conduct (refer to FIG. 2). In an instance in which the parasitic pn diodes conduct, the conduction resistance of the parasitic pn diodes is reduced by conductivity modulation and the slope of the IV waveforms of the internal diodes varies greatly. To obtain an effect (suppression of operation of the parasitic pn diodes of the MOSFET) induced by providing by the trench SBDs 20, the concentration of the n-type impurity of the SBD portions 21 suffices to be set so that the trench SBDs 20 conduct by a forward voltage lower than the forward voltage for the current density at the inflection point of the IV waveform of the internal diodes.

FIG. 5 is a characteristics diagram showing results of simulation of a relationship between the concentration of the n-type impurity of the SBD portions of the silicon carbide semiconductor device 10 and the current density at the inflection point. From the results shown in FIG. 5, it was confirmed that when the concentration of the n-type impurity of the SBD portions 21 is reduced, the conduction resistance of the trench SBDs 20 increases and the current density at the inflection point of the IV waveform of the parasitic pn diodes decreases. During steady operation, to avoid adversely affecting the operation of the MOSFET by the parasitic pn diodes of the MOSFET conducting sooner than the trench SBDs 20, preferably, at least the current density at the inflection point of the IV waveform of the parasitic pn diodes is at least the rated current density (in the first embodiment, for example, about 500 A/cm²: dashed line in FIG. 5) of the MOSFET.

Thus, from the results shown in FIG. 5, the concentration of the n-type impurity of the SBD portions 21 is at least about 1×10¹⁶/cm³. For example, in an instance in which the concentration of the n-type impurity of the upper JFET portions 3a is 1×10¹⁷/cm³ (a same n-type impurity concentration as that at a simulation point farthest on the left side in FIG. 5), the concentration of the n-type impurity of the SBD portions 21 is about 10% or more of the concentration of the n-type impurity of the upper JFET portions 3a. In other words, to reduce the SBD leakage current density and keep the current density at the inflection point of the IV waveform of the parasitic pn diodes of the MOSFET at least equal to the rated current density of the MOSFET, the concentration of the n-type impurity of the SBD portions 21 suffices to be set in a range of 10% to less than 100% of the concentration of the n-type impurity of the upper JFET portions 3a.

Further, the width W1 of the SBD portions 21 was verified. FIG. 6 is a characteristics diagram showing results of simulation of a relationship between the SBD leakage current density and the width of the SBD portions of the silicon carbide semiconductor device according to the first embodiment. Results of simulation of the relationship between the width W1 of each of the SBD portions 21 and the SBD leakage current density when the MOSFET is in the off-state are indicated by a solid line in FIG. 6. Further, in FIG. 6, the SBD leakage current density when the silicon carbide semiconductor device 110 of the reference example free of the SBD portions (refer to FIG. 12) is in the off-state is indicated by a dashed line. From the results shown in FIG. 6, it was confirmed that the greater is the width W1 of each of the SBD portions 21, the lower is the SBD leakage current density.

Further, to avoid adversely affecting the specific on-resistance of the MOSFET, preferably, the width W1 of the SBD portions may be in a range (in the first embodiment, for example, not more than about 0.5 μm) so that even at the upper limit, the SBD portions 21 are apart from the lower JFET portions 3b. A reason for this is that, when the SBD portions 21 extend away from the sidewalls of the Schottky trenches 7b in the second direction Y to an extent of being in contact with the upper surfaces of the lower JFET portions 3b, the path of the main current of the MOSFET narrows during steady operation, leading to increases in the specific on-resistance of the MOSFET. The SBD portions 21 being apart from the lower JFET portions 3b may be rephrased as an interface between any one of the SBD portions 21 and an adjacent one of the upper JFET portions 3a being positioned closer to a center of an adjacent one of the second high-concentration regions 11b than is an interface between the adjacent one of the second high-concentration regions 11b and an adjacent one of the lower JFET portions 3b.

FIG. 7 is a characteristics diagram showing results of simulation of the relationship between the current density at the inflection point and the width of the SBD portions of the silicon carbide semiconductor device 10. Results of simulation of the relationship between the width W1 of each of the SBD portions 21 and the current density at the inflection point of the IV waveform (refer to FIG. 2) of the internal diodes are shown in FIG. 7. From the results shown in FIG. 7, it was confirmed that the narrower is the width W1 of each of the SBD portions 21, the higher is the current density at the inflection point of the IV waveform of the internal diodes. When the width W1 of each of the SBD portions 21 is too narrow, control of the width W1 becomes difficult and thus, preferably, the width W1 of each of the SBD portions 21 may be about 0.1 μm or greater. Thus, preferably, the width W1 of each of the SBD portions 21 may be, for example, in a range of about 0.1 μm to 0.5 μm (a range so as to be apart from the lower JFET portions 3b).

As described, according to the first embodiment, the n-type current spreading regions include the upper JFET portions in contact with the gate insulating films at the sidewalls of the gate trenches and the SBD portions in contact with the Schottky electrodes at the sidewalls of the Schottky trenches. The trench SBDs are formed along the sidewalls of the Schottky trenches and utilize the rectification of the Schottky barriers formed by the junctions between the surfaces of Schottky electrodes and the surfaces of the SBD portions. As a result, during steady operation of the MOSFET, the main current flows to the upper JFET portions, which have a relatively high impurity concentration, and increases of a specific on-resistance may be suppressed. During load short-circuit, leakage current flowing through the trench SBDs is suppressed by the SBD portions, which have a relatively low impurity concentration. Thus, enhancement of the short-circuit withstand capability is possible together with suppression of increases of the specific on-resistance. The concentration of the n-type impurity of the SBD portions may be reproduced and controlled by the dose of the ion-implanted n-type impurity and thus, adverse effects on manufacturing yield due to decreasing the concentration of the n-type impurity of the SBD portions as compared to the concentration of the n-type impurity of the upper JFET portions are small.

A structure of a silicon carbide semiconductor device according to a second embodiment is described with reference to a cross-sectional view in FIG. 8. The second embodiment differs from the first embodiment (refer to FIG. 1) in that SBD portions 51 (hatched portions) are doped with nitrogen, which is an n-type impurity (first-conductivity-type impurity), and co-doped (additionally doped) with aluminum (Al), which is a p-type impurity (second-conductivity-type impurity). Configuration of the SBD portions 51 excluding the co-doping of aluminum and a later-described nitrogen concentration range is the same as that of the SBD portions 21 doped with only nitrogen in the first embodiment.

In the second embodiment, the actual n-type impurity concentration due to nitrogen, which constitutes majority carriers (electrons), is compensated by aluminum, which constitutes minority carriers (holes), and the SBD portions 51 are n-type regions with a carrier concentration (compensated concentration) lower than that of the upper JFET portions 3a. The ionization rate of aluminum is dependent on temperature and when the device temperature increases (for example, about 500 degrees C.) due to load (load turned off and on by the MOSFET) short-circuit, aluminum in the SBD portions 51 is ionized at a rate of nearly 100% and the concentration of the SBD portions 51 is compensated and reduced according to the concentration of the holes released from aluminum.

Rectification of Schottky barriers formed by junctions between the surfaces of the Schottky electrodes 17 and the surfaces of the SBD portions 51 is used to thereby form trench SBDs 52. Other than the SBD portions 51, configuration of the trench SBDs 52 is the same as that of the trench SBDs 20 of the first embodiment. In other words, during load short-circuit, the n-type carrier concentration of the SBD portions 51 is obtained by subtracting from the nitrogen concentration of the SBD portions 51, a product obtained by multiplying the aluminum concentration by the ionization rate. The SBD portions 51 forming the trench SBDs 52 have a lowered compensated concentration, whereby similar to the first embodiment, during load short-circuit, leakage current flowing through the trench SBDs 52 may be reduced (refer to T. Kimoto and J. A. Cooper, “Fundamentals of Silicon Carbide Technology: Growth, Characterization, Devices and Applications”, November 2014, Wiley-IEEE Press, pp. 487).

The carrier concentration of the SBD portions 51 is a compensated concentration obtained by compensating the concentration of the n-type impurity doped and activated in the SBD portions 51, by the concentration of the p-type impurity co-doped and activated in the SBD portions 51. The carrier concentration of the SBD portions 51, similar to the SBD portions 21 in the first embodiment, is lower than the concentration of the n-type impurity of the upper JFET portions 3a. Thus, the second embodiment also has characteristics similar to the verification simulation results shown in FIGS. 2 to 7. During load short-circuit, preferably, the carrier concentration of the SBD portions 51 may be lower than the concentration of the n-type impurity of the upper JFET portions 3a, and the SBD portions 51 and the upper JFET portions 3a may have substantially the same n-type impurity concentration.

Portions of the SBD portions 51 adjacent to the Schottky trenches 7b have a function of mitigating electric field applied to the trench SBDs 52. The nitrogen concentration of the SBD portions 51 is in a range of, for example, about 1×10¹⁶/cm³ to 7×10¹⁷/cm³. When the nitrogen concentration of the SBD portions 51 is less than the lower limit, the conduction resistance of the trench SBDs 52 increases and the current density at the inflection point of the IV waveform of the parasitic pn diodes of the MOSFET (silicon carbide semiconductor device 50) decreases, and thus, is undesirable. The SBD portions 51 have an aluminum concentration in a range of, for example, 10% (preferably, 50% or greater) to less than 100% of the nitrogen concentration of the SBD portions 51.

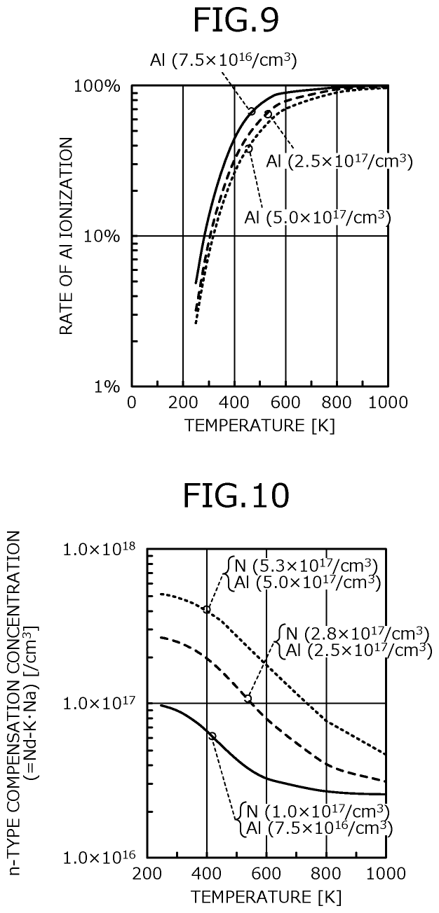

Temperature variation of the ionization rate of a p-type impurity (acceptor) is greatly dependent on the depth of the acceptor level (refer to later-described FIG. 9). Thus, as a p-type impurity co-doped in the SBD portions 51, a p-type impurity is used whereby the ionization rate at the device temperature (for example, about 500 degrees C.) during load short-circuit becomes greater than the ionization rate at the device temperature (for example, about 175 degrees C.) of the MOSFET during steady operation. In particular, as the p-type impurity co-doped in the SBD portions 51, other than using aluminum, gallium (Ga) or boron (B (shallow boron)) with a level as an acceptor deeper than that of aluminum may be used.

A method of manufacturing the silicon carbide semiconductor device 50 according to the second embodiment is described. The second embodiment differs from the first embodiment in that in the portion that increases the thickness of the n-type silicon carbide layer 32, ion-implantation of nitrogen and ion-implantation of aluminum are performed in the formation regions of the SBD portions 51 so as to have the described nitrogen concentration range and the described aluminum concentration range. A sequence in which the ion-implantation of nitrogen and the ion-implantation of aluminum for forming the SBD portions 51 are performed may be suitably set.

In particular, in the second embodiment, after the thickness of the n-type silicon carbide layer 32 is increased but before the p-type silicon carbide layer 33 is epitaxially grown, an ion implantation mask opened at portions corresponding to the formation regions of the SBD portions 51 suffices to be formed at the surface of the n⁻-type silicon carbide layer 32 and the ion-implantation of nitrogen and the ion-implantation of aluminum suffice to be performed using the mask. A sequence in which the upper JFET portions 3a and the SBD portions 21 are formed in the portion increasing the thickness of the n-type silicon carbide layer 32 may be suitably set. The ion-implantation of nitrogen for forming the SBD portions 51 may be performed concurrently with the ion-implantation of nitrogen for forming the upper JFET portions 3a.

Operation of the silicon carbide semiconductor device according to the second embodiment is described. As described above, of the n-type current spreading regions 3, aluminum, which is a p-type impurity, is co-doped only in the SBD portions 51, at a concentration lower than the concentration of the nitrogen. The ionization rate of aluminum increases when the device temperature increases, thereby lowering and compensating the concentration of the SBD portions 51. In other words, the carrier concentration of the SBD portions 51 decreases the higher is the device temperature. Therefore, the SBD portions 51 have a lowered compensated concentration during a load short-circuit during which the device temperature increases more than during steady operation of the MOSFET.

During a load short-circuit, the SBD portions 51 have a lowered compensated concentration, whereby short-circuit current is suppressed and thus, similar to the first embodiment, temperature increases due to short-circuit current are suppressed and increases in leakage current flowing through the trench SBDs 52 may be suppressed. Further, during a load short-circuit, the SBD portions 51 have a lowered compensated concentration, whereby spreading of a depletion layer from junctions between the surfaces of the Schottky electrodes 17 and the surfaces of the SBD portions 51 is facilitated and the electric field strength of the junctions between the surfaces decreases. Thus, electric field applied to the trench SBDs 52 is mitigated and leakage current flowing through the trench SBDs 52 may be reduced.

Accordingly, temperature increases due to leakage current are suppressed and thermal destruction of the MOSFET (the silicon carbide semiconductor device 50) may be suppressed, whereby the short-circuit withstand capability may be enhanced. Further, aluminum is co-doped in the SBD portions 51, whereby leakage current flowing through the trench SBDs 52 during a load short-circuit decreases and thus, relatively reducing the nitrogen concentration of the SBD portions 51 of the n-type current spreading regions 3 is unnecessary to reduce leakage current flowing through the trench SBDs 52. Thus, increases of the specific on-resistance may be suppressed and the short-circuit withstand capability may be enhanced.

Operation the silicon carbide semiconductor device 50 according to the second embodiment during steady operation and during the off-state is the same as that of the silicon carbide semiconductor device 10 according to the first embodiment.

A relationship between the device temperature and the concentration of the n-type impurity of the SBD portions 51 of the silicon carbide semiconductor device 50 was verified. FIG. 9 is a characteristics diagram showing the relationship between temperature and the ionization rate of aluminum for the silicon carbide semiconductor device according to the second embodiment. FIG. 10 is a characteristics diagram showing the relationship between device temperature and compensated n-type impurity concentration for the silicon carbide semiconductor device according to the second embodiment.

FIG. 9 shows temperature characteristics of the ionization rate of aluminum (Al ionization rate) doped in the silicon carbide semiconductor, from FIG. 4 of International Publication No. WO 2022/244749. In the multiple samples of differing aluminum concentrations depicted in FIG. 9, it was found that as the temperature increases, the ionization rate of aluminum increases and becomes saturated at nearly 100% at a temperature of 800K or higher. In FIG. 9, on a horizontal axis indicating temperature, 800K corresponds to about 500 degrees C., which is the device temperature during a load short-circuit in the second embodiment. Further, from the temperature characteristics depicted in FIG. 9, it was found that temperature variation of the ionization rate of aluminum exhibits nearly the same trend regardless of the aluminum concentration.

FIG. 10 shows temperature characteristics of the compensated n-type impurity concentration of the silicon carbide semiconductor doped with nitrogen and aluminum, from FIG. 5 of International Publication No. WO 2022/244749. The compensated n-type concentration is the concentration of carriers that effectively contribute to electrical conduction and thus, may be rephrased as the carrier concentration. The aluminum concentration of the samples in FIG. 10 corresponds to the aluminum concentration of the samples in FIG. 9. In FIG. 10, the compensated n-type impurity concentration is calculated by subtracting from the nitrogen concentration (donor concentration Nd) (=Nd−K·Na), a product obtained by multiplying the ionization rate (K) by the aluminum concentration (acceptor concentration Na). The ionization rate (K) is temperature dependent and is a positive constant not more than 1.

The n-type silicon carbide semiconductor doped with nitrogen and aluminum depicted in FIG. 10 corresponds to the SBD portions 51 of the second embodiment. From the temperature characteristics shown in FIG. 10, it is surmised that the compensated n-type impurity concentration of the n-type silicon carbide semiconductor (i.e., the SBD portions 51) doped with nitrogen and aluminum is lower, the higher is the device temperature (the temperature of the semiconductor substrate 30). Thus, from the temperature characteristics shown in FIGS. 9 and 10, it is surmised that by co-doping aluminum in the SBD portions 51, the compensated concentration of the SBD portions 51 may be reduced according to increases in the device temperature.

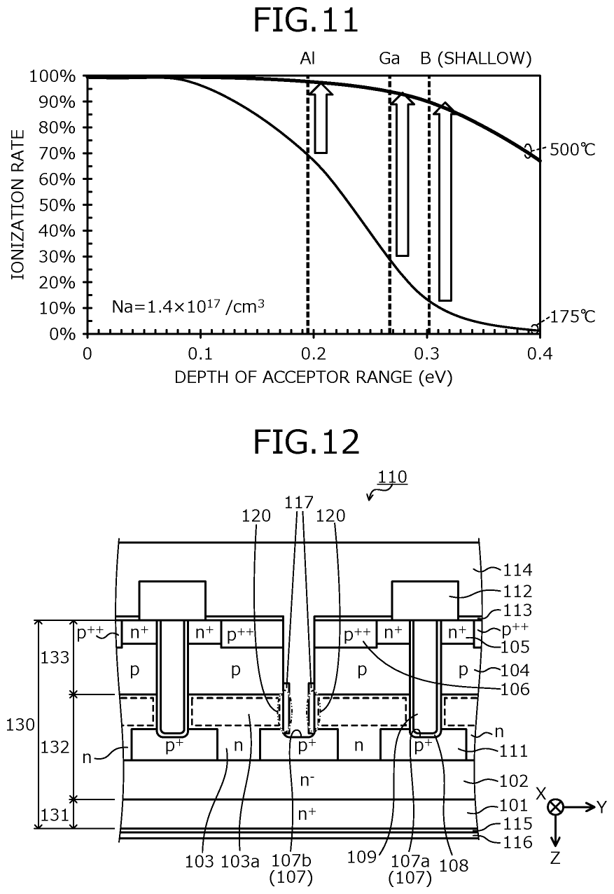

The ionization rate of the p-type impurity was verified. FIG. 11 is a characteristics diagram showing results of simulation of temperature characteristics of the ionization rate of the p-type impurity. For multiple p-type impurities, the concentration thereof (acceptor concentration Na) was assumed to be 1.4×10¹⁷/cm³ and temperature characteristics of the ionization rate were simulated for 175 degrees C. (device temperature during steady operation of the MOSFET) and 500 degrees C. (device temperature during load short-circuit), and the results are shown in FIG. 11.

As the p-type impurity co-doped in the SBD portions 51 described above, a preferable p-type impurity has an ionization rate that is larger at the device temperature during a load short-circuit than at the device temperature during steady operation of the MOSFET and from the results shown in FIG. 11, it was found that other than aluminum, gallium or boron, which have a deep acceptor level at least equal to that of aluminum may be used.

As described above, according to the second embodiment, aluminum is co-doped in the SBD portions, whereby the carrier concentration of the SBD portions during load short-circuit by which the device temperature increases is lowered and compensated and thus, effects similar to those of the first embodiment may be obtained. Further, according to the second embodiment, the carrier concentration of the SBD portions during a load short-circuit has, as an upper limit, the amount by which the concentration is lowered and compensated, the concentration of the n-type impurity of the SBD portions may be increased, and the specific on-resistance may be increased by the amount that the concentration of the n-type impurity of the SBD portions is increased.

The first embodiment and the second embodiment are similar to each other in that the carrier concentration of the SBD portions is lower than the concentration of the n-type impurity added to the upper JFET portion. Further, the first embodiment and the second embodiment are similar in that the lower limit of the carrier concentration of the SBD portions is 10% or more of the concentration of the n-type impurity added to the upper JFET portion. The first embodiment and the second embodiment differ on the following point.

In the first embodiment, the carrier concentration of the SBD portions is substantially equal to the concentration of the n-type impurity added thereto. A reason for this is that the n-type impurity is activated nearly 100% in the expected operating temperature range of the MOSFET and carriers (electrons) are released. In other words, the carrier concentration of the SBD portions is determined by the concentration of the n-type impurity added thereto. Thus, in the first embodiment, it is assumed that only an n-type impurity is substantially added to the upper JFET portion and the SBD portions. Substantially means that other impurities may be added to an extent that the significance of the embodiment is not adversely impacted. More specifically, an allowed amount of other impurities is not more than about 1/100 of an impurity intentionally added or not more than about 1/1000.

On the other hand, in the second embodiment, an n-type impurity and a p-type impurity are both added to the SBD portions. Thus, the carrier concentration of the SBD portions is determined by the concentration (=Nd−K·Na) obtained by subtracting a product obtained by multiplying the ionization rate (K) by the concentration of the p-type impurity (Na), from the concentration (Nd) of the added n-type impurity. A reason for this is that while the n-type impurity is activated nearly 100% in the expected operating temperature range of the MOSFET and carriers (electrons) are released, the rate of ionization (K) of the p-type impurity varies depending on the temperature and the concentration of the released carriers (holes) varies. Thus, in the second embodiment, the carrier concentration of the SBD portions is determined by the described compensated concentration (=Nd−K·Na).

Impurity elements and impurity concentrations in the semiconductor device may be measured by secondary ion mass spectrometry (SIMS). Depending on the shape of the semiconductor device, measurement by Auger electron spectroscopy (AES) may be used in combination as auxiliary data. The carrier concentration in the semiconductor element may be determined based on the impurity concentration measured by the above-described methods, with reference to the ionization rate calculated from the depth and density of the dopant level as depicted in FIG. 11. Depending on the shape of the semiconductor device, measurement by a scanning microwave impedance microscope (sMIM) may be used in combination as auxiliary data.

In the foregoing, the present disclosure is not limited to the embodiments described above and various modifications not departing from the spirit of the disclosure are possible. For example, in the embodiments described above, in the n-type current spreading regions, an n-type impurity other than nitrogen (for example, phosphorus (P) or the like) may be doped as the n-type impurity (donor).

According to the disclosure described above, during operation of a MOS-type silicon carbide semiconductor device having insulated gates with a three-layer metal-oxide-semiconductor structure, current flows through the upper JFET portion, which has a relatively low impurity concentration, and thus, increases in the on-resistance may be suppressed. During a load short-circuit, leakage current flowing through the Schottky barrier diodes (SBD) is suppressed by the SBD portions, which have relatively low impurity concentrations, and thus, short-circuit withstand capability is enhanced.

The silicon carbide semiconductor device according to the present disclosure achieves an effect in that short-circuit withstand capability may be enhanced together with suppressing increases in on-resistance.

As described above, the silicon carbide semiconductor device according to the present disclosure is useful for power semiconductor devices used in power converting equipment, power source devices of various industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate containing silicon carbide, the semiconductor substrate having a first main surface and a second main surface opposite to each other;
a first semiconductor region of a first conductivity type, provided in the semiconductor substrate;
a second semiconductor region of a second conductivity type, provided between the first main surface of the semiconductor substrate and the first semiconductor region;
a third semiconductor region of the first conductivity type, selectively provided between the first main surface of the semiconductor substrate and the second semiconductor region;
a fourth semiconductor region of the first conductivity type, provided between, and in contact with, the second semiconductor region and the first semiconductor region, the fourth semiconductor region having a first-conductivity-type impurity, which is an impurity of the first conductivity type, added thereto, a concentration of the first-conductivity-type impurity being higher than an impurity concentration of the first semiconductor region;
a plurality of trenches, each having a predetermined depth from the first main surface of the semiconductor substrate, the plurality of trenches including:
a first trench penetrating through the third semiconductor region and the second semiconductor region in a depth direction of the device, and terminating in the fourth semiconductor region, and
a second trench penetrating through the second semiconductor region in the depth direction and terminating in the fourth semiconductor region, the second trench being separate from the third semiconductor region;
a gate insulating film provided in the first trench;
a gate electrode provided in the first trench, on the gate insulating film;
a Schottky electrode formed at an inner wall of the second trench, the Schottky electrode being in contact with the fourth semiconductor region;
a first electrode electrically connected to the second semiconductor region and the third semiconductor region, the first electrode being embedded in the second trench and in contact with the Schottky electrode; and
a second electrode electrically connected to the second main surface of the semiconductor substrate, wherein
the fourth semiconductor region includes:
a Schottky barrier diode (SBD) portion of the first conductivity type, formed at a sidewall of the second trench and in contact with the Schottky electrode, and
an upper junction field effect transistor (JFET) portion of the first conductivity type, provided between a sidewall of the first trench and the SBD portion;
a junction between a surface of the Schottky electrode and a surface of the SBD portion forms an SBD; and
a carrier concentration of the SBD portion is lower than the concentration of the first-conductivity-type impurity added to the upper JFET portion.

2. The silicon carbide semiconductor device according to claim 1, wherein
in the SBD portion, only the first-conductivity-type impurity is substantially added,
the carrier concentration of the SBD portion is determined by the concentration of the first-conductivity-type impurity added to the SBD portion, and
the concentration of the first-conductivity-type impurity added to the SBD portion is at least 1×10¹⁶/cm³ and is in a range of 10% to less than 100% of the concentration of the first-conductivity-type impurity added to the upper JFET portion.

3. The silicon carbide semiconductor device according to claim 1, wherein
the first-conductivity-type impurity and a second-conductivity-type impurity, which is an impurity of the second conductivity type, are added to the SBD portion, and
the carrier concentration of the SBD portion is determined by a concentration obtained by subtracting from the concentration of the first-conductivity-type impurity added to the SBD portion, a product obtained by multiplying an ionization rate by a concentration of the second-conductivity-type impurity.

4. The silicon carbide semiconductor device according to claim 3, wherein the second-conductivity-type impurity is aluminum, gallium, or boron.

5. The silicon carbide semiconductor device according to claim 1, further comprising:
a fifth semiconductor region of the second conductivity type, provided between the second semiconductor region and the first semiconductor region, the fifth semiconductor region being apart from the second semiconductor region and facing a bottom of the first trench; and
a sixth semiconductor region of the second conductivity type, provided between the second semiconductor region and the first semiconductor region, the sixth semiconductor region being apart from the second semiconductor region and facing a bottom of the second trench, the sixth semiconductor region being adjacent to the fifth semiconductor region in a direction parallel to the first main surface of the semiconductor substrate, wherein
the fourth semiconductor region further includes a lower JFET portion of the first conductivity type provided between the upper JFET portion and the first semiconductor region, and between the fifth semiconductor region and the sixth semiconductor region, and
the SBD portion is apart from the lower JFET portion.

6. The silicon carbide semiconductor device according to claim 1, further comprising:
a fifth semiconductor region of the second conductivity type, provided between the second semiconductor region and the first semiconductor region, the fifth semiconductor region being apart from the second semiconductor region and facing a bottom of the first trench; and
a sixth semiconductor region of the second conductivity type, provided between the second semiconductor region and the first semiconductor region, the sixth semiconductor region being apart from the second semiconductor region and facing a bottom of the second trench, wherein
a distance from the junction between the surface of the Schottky electrode and the surface of the SBD portion to an interface between the upper JFET portion and the SBD portion is smaller than a distance by which the sixth semiconductor region protrudes away from the sidewall of the second trench, in a direction parallel to the first main surface of the semiconductor substrate.

7. The silicon carbide semiconductor device according to claim 6, wherein the distance from the junction between the surface of the Schottky electrode and the surface of the SBD portion to the interface between the upper JFET portion and the SBD portion is in a range of 0.1 μm to 0.5 μm.

8. The silicon carbide semiconductor device according to claim 1, wherein the first-conductivity-type impurity is nitrogen.
